(19) United States
(12) Patent Application Publication
(10) Pub. No.: US 2011/0089832 A1
(43) Pub. Date: Apr. 21, 2011

(54) SEALED OUTER ENVELOPE THAT HOUSES A COMPACT FLUORESCENT LAMP TO PREVENT MERCURY VAPOR RELEASE TO THE ENVIRONMENT IN CASE OF DAMAGE TO THE COMPACT FLUORESCENT LAMP

(76) Inventor: Gregory J. Kelly, Duluth, GA (US)

(21) Appl. No.: 12/582,147

(22) Filed: Oct. 20, 2009

(51) Int. Cl. H01J 5/02; H05K 5/06

(52) U.S. Cl. 315/56; 174/50.5

(57) ABSTRACT

A sealing structure that hermetically seals an open end of an outer envelope to a lamp base of a compact fluorescent bulb to prevent release of mercury to the environment. The sealing structure may be a tightened band, snapped together structures or an adhesive. The outer envelope is resistant to tearing from shards of glass in the event of breakage of the bulb and resistant to heat given off by the bulb during illumination so as to maintain and integrity of the outer envelope throughout exposure to the heat. The sealing structure and outer envelope may be packaged together as a kit.

### BACKGROUND OF THE INVENTION

The invention relates to preventing release of mercury vapors to the environment due to breakage of compact fluorescent lamps, and more particularly to a sealed outer envelopes that house compact fluorescent lamps.

The operation of fluorescent lamps is conventional, as set forth in the following excerpt in paragraphs [0003]-[0015] from an article entitled HOW FLORESCENT LAMPS WORK by Tom Harris at: http://home.howstuffworks.com/fluorescent-lamp6.htm.

The central element in a fluorescent lamp is a sealed glass tube. The tube contains a small bit of mercury and an inert gas, typically argon, kept under very low pressure. The tube also contains a phosphor powder, coated along the inside of the glass. The tube has two electrodes, one at each end, which are wired to an electrical circuit. The electrical circuit, which we'll examine later, is hooked up to an alternating current (AC) supply.

When one turns the compact fluorescent lamp on, the current flows through the electrical circuit to the electrodes. There is a considerable voltage across the electrodes, so electrons will migrate through the gas from one end of the tube to the other. This energy changes some of the mercury in the tube from a liquid to a gas. As electrons and charged atoms move through the tube, some of them will collide with the gaseous mercury atoms. These collisions excite the atoms, bumping electrons up to higher energy levels. When the electrons return to their original energy level, they release light photons.

The wavelength of a photon is determined by the particular electron arrangement in the atom. The electrons in mercury atoms are arranged in such a way that they mostly release light photons in the ultraviolet wavelength range. Human eyes don't register ultraviolet photons, so this sort of light needs to be converted into visible light to illuminate the lamp.

This is where the tube's phosphor powder coating comes in. Phosphors are substances that give off light when they are exposed to light. When a photon hits a phosphor atom, one of the phosphor's electrons jumps to a higher energy level and the atom heats up. When the electron falls back to its normal level, it releases energy in the form of another photon. This photon has less energy than the original photon, because some energy was lost as heat. In a fluorescent lamp, the emitted light is in the visible spectrum—the phosphor gives off white light we can see. Manufacturers can vary the color of the light by using different combinations of phosphors.

Conventional incandescent light bulbs also emit a good bit of ultraviolet light, but they do not convert any of it to visible light. Consequently, a lot of the energy used to power an incandescent lamp is wasted. A fluorescent lamp puts this invisible light to work, and so is more efficient. Incandescent lamps also lose more energy through heat emission than do fluorescent lamps. Overall, a typical fluorescent lamp is four to six times more efficient than an incandescent lamp. People generally use incandescent lights in the home, however, since they emit a “warmer” light—a light with more red and less blue.

The entire fluorescent lamp system depends on an electrical current flowing through the gas in the glass tube. In a gas, electrical charge is carried by free electrons moving independently of atoms. Current is also carried by ions, atoms that have an electrical charge because they have lost or gained an electron. Like electrons, ions are drawn to oppositely charged areas.

The lamp's ballast constantly channels current through both electrodes. This current flow is configured so that there is a charge difference between the two electrodes, establishing a voltage across the tube. When the fluorescent light is turned on, both electrode filaments heat up very quickly, boiling off electrons, which ionize the gas in the tube. Once the gas is ionized, the voltage difference between the electrodes establishes an electrical arc. The flowing charged particles excite the mercury atoms, triggering the illumination process.

An alternative method, used in instant-start fluorescent lamps, is to apply a very high initial voltage to the electrodes. This high voltage creates a corona discharge. Essentially, an excess of electrons on the electrode surface forces some electrons into the gas. These free electrons ionize the gas, and almost instantly the voltage difference between the electrodes establishes an electrical arc.

No matter how the starting mechanism is configured, the end result is the same: a flow of electrical current through an ionized gas. This sort of gas discharge has a peculiar and problematic quality: If the current isn't carefully controlled, it will continually increase, and possibly explode the light fixture. In a gas discharge, such as a fluorescent lamp, current causes resistance to decrease. This is because as more electrons and ions flow through a particular area, they bump into more atoms, which frees up electrons, creating more charged particles. In this way, current will climb on its own in a gas discharge, as long as there is adequate voltage (and household AC current has a lot of voltage). If the current in a fluorescent light isn't controlled, it can blow out the various electrical components.

A fluorescent lamp's ballast works to control this. The simplest sort of ballast, generally referred to as a magnetic ballast, works something like an inductor. A ballast can only slow down changes in current—it can't stop them. But the alternating current powering a fluorescent light is constantly reversing itself, so the ballast only has to inhibit increasing current in a particular direction for a short amount of time.

Magnetic ballasts modulate electrical current at a relatively low cycle rate, which can cause a noticeable flicker. Magnetic ballasts may also vibrate at a low frequency. This is the source of the audible humming sound people associate with fluorescent lamps.

Modern ballast designs use advanced electronics to more precisely regulate the current flowing through the electrical circuit. Since they use a higher cycle rate, you don't generally notice a flicker or humming noise coming from an electronic ballast. Different lamps require specialized ballasts designed to maintain the specific voltage and current levels needed for varying tube designs.

Fluorescent lamps come in all shapes and sizes, but they all work on the same basic principle: An electric current stimulates mercury atoms, which causes them to release ultraviolet photons. These photons in turn stimulate a phosphor, which emits visible light photons.

The contents of U.S. patent application publication no. US 2007/0063656 A1 is incorporated herein by reference, which shows an outer envelope hermetically sealed to a base of a compact fluorescent lamp. The outer envelope may be transparent or translucent and has a substantially spherical portion and an elongated end portion.

A conventional compact fluorescent tube may include a glass tube to enclose a discharge volume filled with a discharge gas and has a fluorescent phosphor coating disposed on the inner surface of the tube. The tube forms a continuous arc path and is provided with electrodes disposed at each end of the arc path. The lamp also comprises a ballast circuit connected to the electrodes for controlling the current in the tube and a lamp base for connecting said lamp to a power supply through a socket. The lamp is provided with an outer envelope comprising a substantially spherical portion enclosing the tube arrangement and an elongated end portion enclosing the ballast circuit. The end portion of the outer envelope is closed and sealed by a sealing means of the same material as the material of the outer envelope. The sealing means is connected to the envelope in a hermetically sealing way.

U.S. Pat. No. 4,527,089 discloses a compact fluorescent lamp comprising multiple, individual tubes mechanically formed into an assembly and inserted into an outer envelope. The individual open-ended tubes are connected to each other through an arc directing means to form a continuous arc path. The outer envelope has a cylindrical shape and is hermetically sealed and includes an arc generating and sustaining medium, such as an atmosphere of mercury and argon. The hermetic seal is mainly used in order to provide a securely closed container for the arc generating and sustaining medium. In case of any damage to the outer envelope, the arc generating and sustaining medium containing mercury is set free, which is harmful to the environment.

U.S. Pat. No. 6,064,155 discloses a fluorescent lamp with an outer envelope having an external shape of an incandescent lamp on a standard Edison-type base. The discharge tube is wound in a coil around the axis of the envelope and is disposed within the outer envelope. A ballast is arranged within the outer envelope, as well. A heat shield is disposed between the lamp and the ballast to thermally isolate the lamp from the ballast, whereby heat from the lamp will not adversely affect the ballast. Insulated connecting wires are used. The outer envelope is not sealed hermetically and therefore the glass tube is not protected against adverse influence of the atmosphere. The discharge tubes are not fixed inside the outer envelope, they are only held by the electrodes.

Accordingly, there is a need for a compact fluorescent lamp configuration to prevent release to the environment of mercury from the compact fluorescent lamp in case of breakage of a glass tube of the lamp.

### SUMMARY OF THE INVENTION

One aspect of the invention resides in an outer envelope for housing a compact fluorescent lamp. The outer envelope is translucent or transparent. Further, the outer envelope is tear resistant to prevent penetration by shards of broken lamp glass and heat resistant to maintain integrity of the outer envelope upon exposure to heat generated by the lamp.

Another aspect of the present invention concerns a method for manufacturing a compact fluorescent lamp. The method comprises the following steps. An outer envelope includes a substantially tubular portion and an elongated end portion being terminated by an open end on the base side. The open end of the elongated portion of the envelope is closed and sealed with a sealing means of the same material to provide a hermetic seal. The sealing means may comprise power supply lead-out wires and an exhaust tube.

An upper part receives a glass tube with lead-in wires and a lower part is closed by the sealing means, and the base side receives a ballast circuit with connection points for the power supply lead-out wires and the lead-in wires of the glass tube. The ballast circuit is introduced into the lower part and the respective connection points of the ballast circuit are connected to the lead-out wires. The lead-in wires of the glass tube are connected to the respective connection points of the ballast circuit. The two separated parts of the envelope are brought into contact with each other along the separating line. The envelope is provided with a base and the lead-out wires are connected to contact terminals of the base.

The disclosed compact fluorescent lamps ensure that the available lamp is well protected against any intrusion of dust and humidity from the outside atmosphere into the inside volume of the outer envelope.

### BRIEF DESCRIPTION OF THE DRAWINGS

The invention will now be described in detail with reference to the enclosed drawings. FIGS. 1-11 show conventional configurations from U.S. patent application publication no. 2007/0063656 and their description are reproduced here.

FIG. 1 is a side view, partially in cross section, showing a conventional compact fluorescent discharge lamp with spherical outer envelope.

FIG. 2 is a side view, partially in cross section, showing another conventional compact fluorescent discharge lamp.

FIG. 3 is a plain spread out view of a glass tube used in the conventional fluorescent discharge lamp shown in FIG. 1.

FIG. 4 is a plain spread out view of another glass tube used in the conventional fluorescent discharge lamp shown in FIG. 1.

FIG. 5 is a schematic diagram of providing an outer envelope in the manufacturing of the conventional fluorescent discharge lamp.

FIG. 6 is a schematic diagram of sealing the outer envelope in the manufacturing of the conventional fluorescent discharge lamp.

FIG. 7 is a schematic diagram of separating the outer envelope in two parts in the manufacturing of the conventional fluorescent discharge lamp.

FIG. 8 is a schematic diagram of inserting and connecting the ballast circuit in the manufacturing of the conventional fluorescent discharge lamp.

FIG. 9 is a schematic diagram of inserting and connecting the glass tube in the manufacturing of the conventional fluorescent discharge lamp.

FIG. 10 is a schematic diagram of connecting and sealing the two parts of the outer envelope and filling/exhausting the envelope in the manufacturing of the conventional fluorescent discharge lamp.

FIG. 11 is a schematic diagram of providing the sealed end of the outer envelope with a base and connection terminals in the manufacturing of the conventional fluorescent discharge lamp.

FIG. 12 is a schematic diagram of a further embodiment that fixes an outer envelope to a lamp base by applying pressure with a further part, such as an elastic band or pipe clamp.

FIG. 13 is a schematic diagram of another embodiment that fixes an outer envelope to a lamp base by mechanical engagement, such as by screwing or snapping together.

FIG. 14 is a schematic diagram of a kit in accordance with the invention to seal an outer envelope to a lamp base.

FIG. 15 is a schematic diagram of a further kit in accordance with the invention to seal an outer envelope to a lamp base.

### DETAILED DESCRIPTION OF THE INVENTION

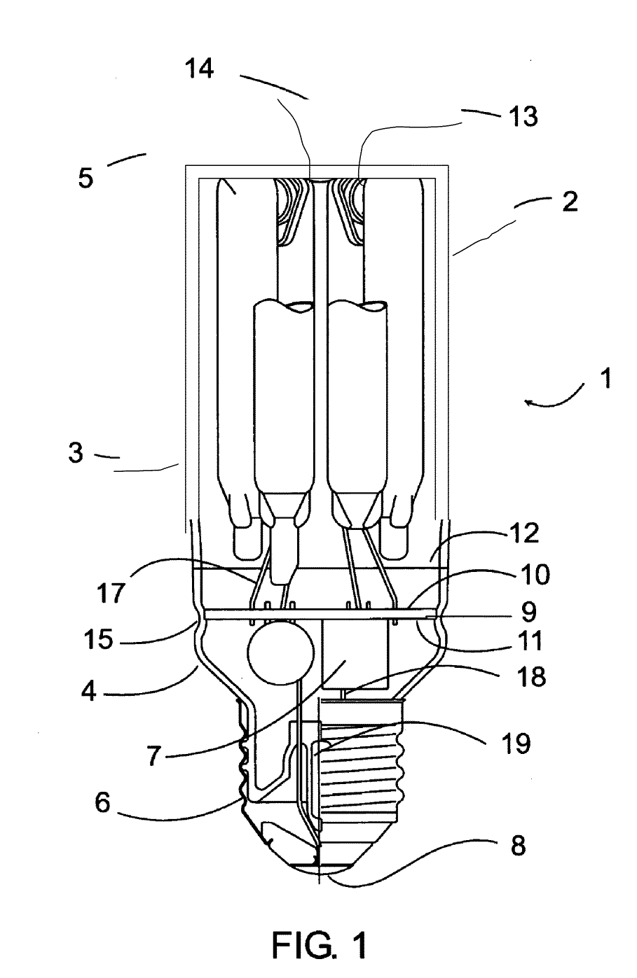

Referring now to FIG. 1, a low-pressure discharge lamp I is shown. The lamp is a fluorescent discharge lamp, with an outer envelope 2 enclosing a glass tube 5 and a ballast circuit 7. The outer envelope 2 may be transparent or translucent, and may be made of plastic, such as polytetrafluoroethylene (PTFE) heat shrink tubing or fluorinated ethylene-propylene (FEP) heat shrink tubing. For instance, such heat shrink tubing may maintain its integrity when subjected to temperatures of 300 degrees Fahrenheit and conventionally have been make to meet US military standards MIL-I-23054/11 or MIL-I-23053/12 with a flame retardant rating for UL94 and VW-1 Flame Test.

The outer envelope 2 has a closed end portion and an elongated open end portion. The outer envelope 2 may be hermetically sealed at its elongated end portion and connected to a base 6. The closed end portion may include a cylindrical segment and a closing segment. The closing segment may be conical, truncated conical, hemispherical or flat.

The outer envelope may or may not be cut in two parts and separated at cutting line 12 in order that the ballast circuit 7 and the glass tube 5 can be inserted and connected inside the outer envelope 2 as described in detail below. The glass tube 5 comprises a plurality of elongated discharge tubes.

The discharge tubes are made of glass, and enclose a discharge volume filled with a discharge gas, and have a fluorescent phosphor coating disposed on the inner surface of the tubes. The ends of the tubes are sealed in a gas tight fashion. The tubes are interconnected by bridges and form a continuous arc path. At the ends of the continuous arc path, the tubes are provided with electrodes and lead-in wires 17 connected to the electrodes. The lead-in wires 17 of the glass tube are connected to a ballast circuit 7 for controlling the current in the discharge tubes. The ballast circuit 7 is further connected through lead-out wires 18 to a power supply. The lead-out wires are connected to contact terminals 8 in the lamp base 6. The lamp base is configured to be adapted to a socket, which may be of any conventional or standard type normally used for incandescent lamps. The lamp base may be configured to fit in a screw-type socket or a bayonet socket.

The ballast circuit 7 is mounted on a printed circuit board 9 which has an assembling side 11 or surface facing toward said base 6, an upper side 10 or surface facing toward said glass tube 5 and an edge portion following the shape of the outer envelope 2 to form a thermal isolating means. The edge portion of the printed circuit board 9 carrying the ballast circuit 7 has advantageously a circular boundary form according to the cross sectional configuration of the wall of the outer envelope 2 taken in cross direction to the principal axis of the lamp 1. The edge portion of the printed circuit board may be provided with slots.

The printed circuit board 9 carrying the ballast circuit 7 comprises connection points for connecting the power supply lead-out wires 18 and the lead-in wires 17 of the electrodes of the discharge tubes. The connection points for connecting the power supply lead-out wires 18 and for connecting the lead-in wires 17 of the electrodes of the discharge tubes are accessible from both the upper side 10 of the printed circuit board facing the glass tube 5 and the assembling side 11 facing toward the base 6.

The upper side 10 surface of the printed circuit board 9 of the ballast circuit 7 may be coated or otherwise provided with a reflecting layer (not shown), which may be adapted to reflect heat or light or both. This reflecting layer must be made of an electrically non-conductive material at least on the side facing the printed circuit board 9. It may be a single layer sheet, a multiple layer sheet, or a paint of at least one layer.

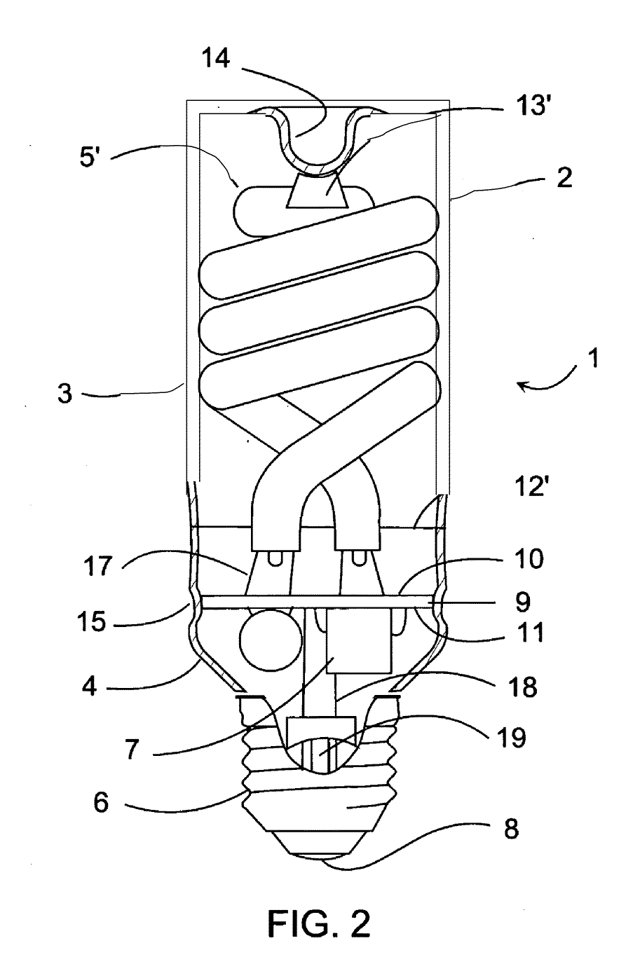

In order to provide a better holding of the printed circuit board 9 of the ballast circuit 7, the outer envelope 2 may have a circumferential groove 15 with an inside surface of the groove being in direct or indirect contact with the printed circuit board 9, as shown in FIGS. 1 and 2. To avoid tension in the envelope wall due to thermal expansion of the printed circuit board 9, a flexible sealing material may be applied between the outer envelope 2 and the edge portion of the printed circuit board 9.

As shown in FIGS. 1 and 2, the glass tube 5 is connected to fixing structure 13 for fixing the position of the glass tube 5 inside the outer envelope 2. The fixing structure 13 may be of metal, plastic or similar material sufficiently strong and flexible in order to hold the glass tube 5 in a fixed position inside the outer envelope 2 and providing sufficient protection against mechanical vibration and shocks. The fixing structure 13 may be connected to the glass tube 5 and the outer envelope 2 in a permanent or a releasable way. Gluing soldering, welding or the like may provide connection that is permanent. A releasable connection may be realized by using clips, snap-in fixtures, springs or the like.

As it can be seen in FIGS. 1 and 2, the outer envelope is provided with an arcuate recess 14 in a middle top region, where the principal axis intersects the outer envelope. The fixing structure 13 is supported by the inside surface of the recessed region of the outer envelope 2 which is reinforced and stabilized in the recess region.

The difference between the embodiments shown in FIGS. 1 and 2 is in the configuration of the glass tube. In the embodiment shown in FIG. 1, the glass tube 5 is comprised of straight sections with a longitudinal axis substantially parallel to the principal axis of the fluorescent lamp. The neighboring discharge tubes are arranged substantially at equal distance from the principal axis of the fluorescent lamp and from each other to provide a substantially homogenous illumination.

The outer envelope 2 may be cut in two parts along a circumferential line in a plane substantially perpendicular to the principal axis of the envelope to form an upper part 3 for receiving the glass tube 5 with lead-in wires and a lower part 4 for receiving a ballast circuit 7 with connection points for power supply lead-out wires and lead-in wires of the glass tube 5. The cutting line 12 is in a position in the outer envelope where the wall of the outer envelope 2 has a substantially cylindrical form. In addition, the cutting line 12 is above the plane of the printed circuit board carrying the ballast circuit at a distance sufficient for thermal protection of the ballast circuit. If the cutting line 12 is set lower, the ballast circuit may be damaged during connecting the two parts by welding.

In the embodiment shown in FIG. 2, the glass tube 5′ is comprised of a single tube with substantially straight end sections and an intermediate portion between the end sections. The end sections are at one end of the tube arrangement 5′ and in proximity to each other and the intermediate portion has a coiled configuration wound about the principal axis of the lamp 1 to provide a substantially homogenous illumination. The outer envelope 2 may be cut in two parts along a circumferential line in a plane substantially perpendicular to the principal axis of the outer envelope 2 to form an upper part 3 for receiving the glass tube 5 with lead-in wires and a lower part 4 for receiving a ballast circuit 7 with connection points for the power supply lead-out wires and lead-in wires of the glass tube 5.

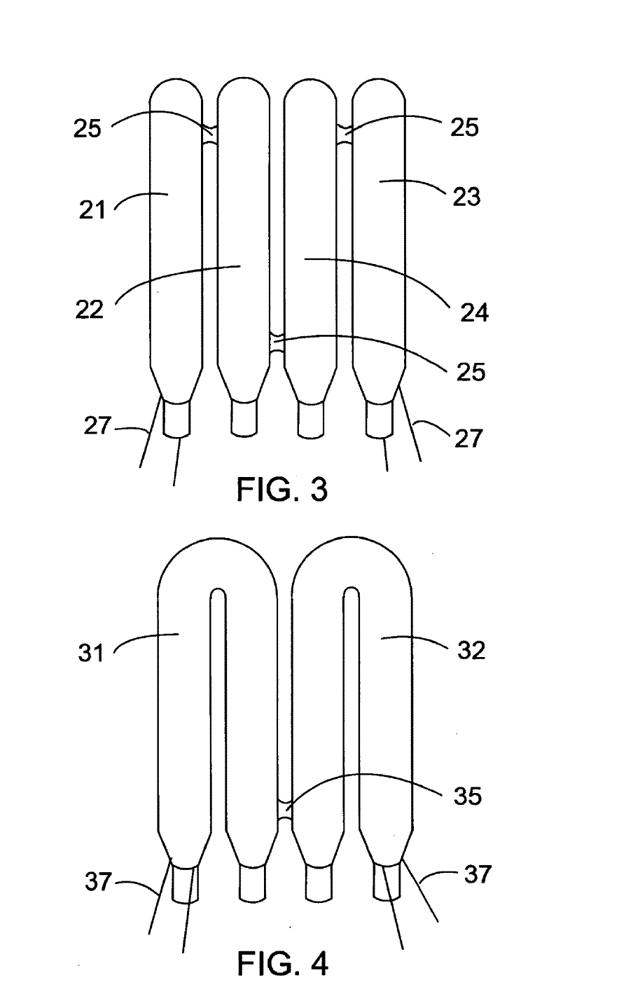

FIGS. 3 and 4 illustrate two specific configurations of the glass tube seen in FIG. 1 comprising substantially straight tube members 21 to 24. In a first embodiment shown in FIG. 3, the glass tube comprises four individual, elongated, substantially parallel straight discharge tube members 21 to 24 of substantially same length, which are interconnected by a bridge 25 to form a continuous arc path. The glass tube is provided with electrodes and lead-in wires 27 connected to the electrodes at both ends of the arc path.

Possible arrangements include also configurations with two or six individual discharge tube members depending on the required output luminous intensity. In a second embodiment shown in FIG. 4, the glass tube comprises two individual, elongated discharge tube members 31 and 32 bent in an U-shape of substantially the same length, which are interconnected by a bridge 35 to form a continuous arc path. The glass tube is provided with electrodes and lead-in wires 37 connected to the electrodes at both ends of the arc path. Possible arrangements include also configurations with one or three individual discharge tubes bent in an U-shape depending on the required output luminous intensity. The U-shaped discharge tube members comprise substantially parallel straight sections defining the length of the glass tube and a curved middle section.

Each discharge tube encloses a discharge volume, which is filled with discharge gas. The discharge tubes are substantially tubular. In the shown embodiment, they are cylindrical, but other suitable cross sections may be selected as well. The discharge tubes are made of glass in the shown embodiments. It is preferred that the wall thickness of the discharge tubes should be substantially constant, mostly from a manufacturing point of view, and also to ensure an even discharge within the discharge tubes along their full length.

In order to provide a visible light, the internal surface of the discharge tubes is covered with a fluorescent phosphor layer (not shown). This phosphor layer is within the sealed discharge volume. The composition of such a phosphor layer is known per se. This phosphor layer converts UV radiation into visible light. The phosphor layer is applied to the inner surface of the discharge tubes before they are sealed.

Turning now to FIG. 5 to FIG. 11, the steps of producing a compact fluorescent lamp with an outer envelope having a sealing structure of plastic. In step one, as depicted in FIG. 5, an outer envelope with a closed end portion and an elongated open end portion is provided. To provide a better support for the printed circuit board carrying the ballast circuit, a circumferential groove may be formed in the elongated open end portion in the lower part of its wide cylindrical region. In step two, as shown in FIG. 6, the open end of the elongated end portion is closed and sealed by a sealing structure, which is preferably a stem. The sealing structure also comprises the power supply lead-out wires and an exhaust tube. As shown in FIG. 6, a stem 40 is introduced into the open end of the elongated end portion of the outer envelope 2 at the base side and sealed hermetically by a flare that is connectable in an air-tight manner to the open end of the outer envelope 2. The exhaust tube 19 extends through the flare for providing gas communication between the inside volume of the outer envelope 2 and the outside atmosphere.

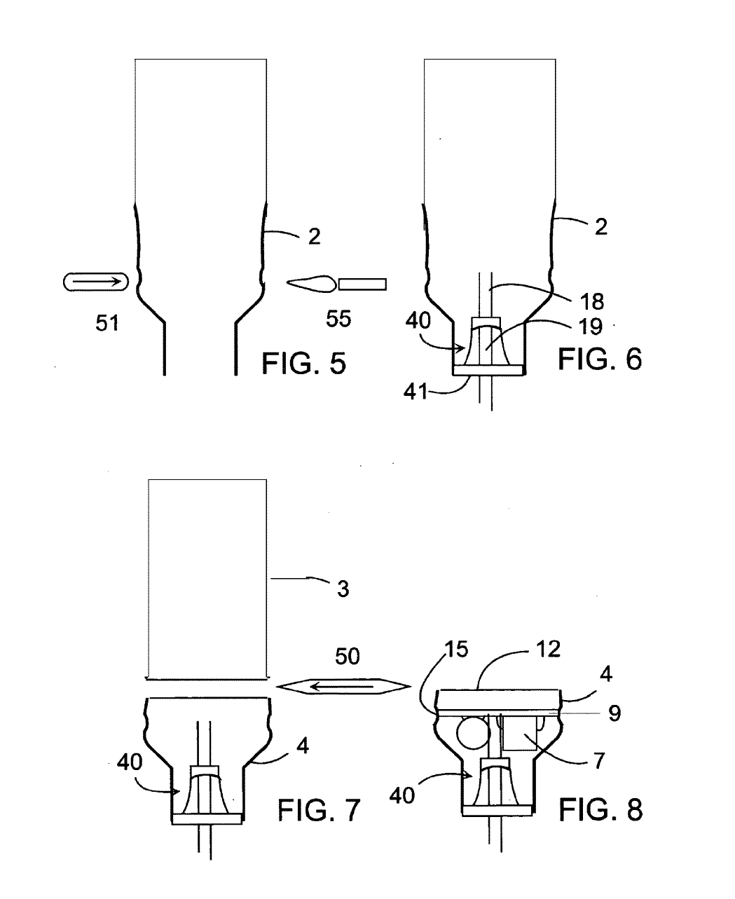

In a third step, as shown in FIG. 7, the outer envelope 2 is cut in two parts with a cutting dye 50. This may preferably be done by rotating the envelope around its principal axis while bringing it into a cutting position of the cutting dye, which is also rotating itself. The separation line created in this way has a circumferential or preferably circular form in a plane substantially perpendicular to the principal axis of the envelope. The upper part 3 is removed from the lower part 4, which houses the stem 40 enclosing the power supply lead-out wires 18 and also comprising an exhaust tube 19. The position of the separation line is selected in a region where the wall of the outer envelope has a substantially cylindrical form above the plane of the printed circuit board carrying the ballast circuit at a distance sufficient to provide thermal protection for the ballast circuit. After providing the envelope or after separating the two parts of the envelope at the latest, the inside surface of the envelope may be coated by a fluorescent phosphor layer.

In a fourth step, as it is illustrated in FIG. 8, the ballast circuit 7 is inserted into the lower part 4 of the outer envelope 2 and connected electrically to the power supply lead-out wires 18. The printed circuit board carrying the ballast circuit may have previously been provided with an elastic sealing material at the edge portion in order to avoid mechanical stress due to thermal expansion. The position of the plane of the printed circuit board carrying the ballast circuit is selected as low as possible in proximity of the stem 40 in order to keep the lead-out wires 18 between the stem and the ballast circuit as short as possible. The use of short lead-out wires prevents these wires from getting short-circuited, and eliminates the need of any insulation of these wires.

In a fifth step, as it is shown in FIG. 9, the glass tube 5 is connected electrically to the ballast circuit 7. In the event that the upper side of the printed circuit board is coated or otherwise provided with a heat or light-reflecting layer, this layer is applied to the upper side of the printed circuit board before the fifth step of assembling the glass tube 5. Irrespective of the type of the reflecting layer, it is important that the means for connecting the lead-in wires of the electrodes remain uncovered and project above the reflecting layer.

In one embodiment, the connection points for electrically connecting the glass tube 5 to the ballast circuit 7 are provided with terminal wires. The terminal wires are connected to the connection points and extend to the assembling side of the printed circuit board of the ballast circuit toward the base. The free ends of the terminal wires are then bent upwards and lead through the slots at the circumferential portion of the printed circuit board of the ballast circuit. The electric connection between the lead-in wires and the free ends of the terminal wires is provided by wrapping the lead-in wires and the terminal wires around each other.

If a fixing structure as shown in FIGS. 1 and 2 is used for fixing the position of the glass tube inside the envelope and for absorbing shocks and vibrations of the envelope, the fixing structure has to be applied to the glass tube before or during this step. The fixing structure has to be strong and flexible in order to provide an effective protection for the glass tube inside the envelope. The material and the shape of the fixing structure has to be selected so as not to decrease the luminous output of the glass tube. Therefore a preferred material is a flexible plastic which is transparent or at least translucent. Securing the fixing elements to the discharge tubes and if required to the envelope can be carried out by a permanent or a releasable connection. A permanent connection will be established preferably by gluing at least one end of the fixing elements while the other end may be secured previously by soldering or welding as well. A releasable connection can be accomplished by using clips, snap-in fixtures, springs or the like.

In a sixth step (FIG. 10), the upper part 3 of the outer envelope is rejoined and sealed in a gas tight fashion with the lower part. In order to accomplish a gas tight connection or seal between the upper part 3 and the lower part 4 of the outer envelope, the two parts may be welded together using a heater 55, which may be a gas heater. The position of the circumferential separation line of the outer envelope has been selected in the region of the elongated portion where the wall of the envelope has a substantially cylindrical form above the plane of the printed circuit board carrying the ballast circuit at a distance sufficient to provide thermal protection of the ballast circuit. The plane of the circumferential separation line and that of the printed circuit board carrying the ballast circuit are separated from each other by a distance, which is at least 10 mm or preferably at least 20 mm. After the two parts are reconnected and sealed, the inside volume of the outer envelope may be filled with air or an inert gas at a normal or decreased atmospheric pressure through the exhaust tube 19 which is sealed afterwards as well known in the art.

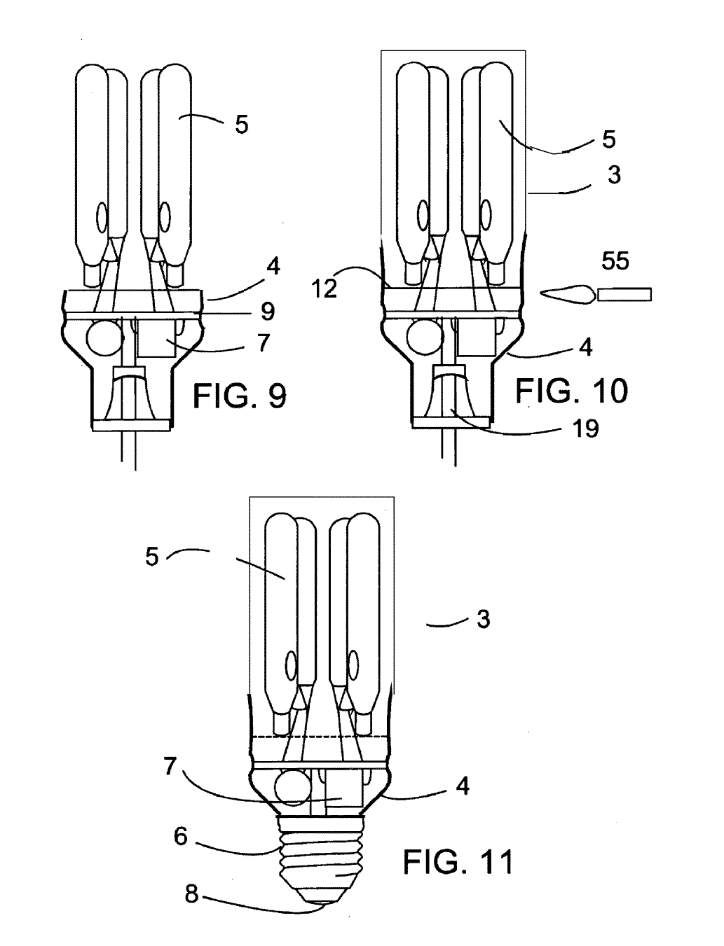

Finally in a seventh step, as it is illustrated in FIG. 11, the fluorescent discharge lamp is completed with a base 6 for connecting the lamp to a conventional or standard socket of any screw-in or bayonet type. In the shown example as it can be seen in FIG. 11, the compact fluorescent lamp is provided with an Edison-type base. The lamp base may be fixed to the base side end of the elongated portion of the outer envelope in a conventional way. In order to increase mechanical strength, the base side end of the elongated portion of the outer envelope may be threaded in a similar way as the Edison-type base, which may than be screwed onto it. The electrical contacts of the power supply lead-out wires and the contact terminals 8 of the base are also created in this step.

A number of other shapes of the outer envelope 2 may be applicable. For example, the envelope may have a spherical, triangular, square, pentagonal or hexagonal cross-section. The general cross-section of the tubular discharge vessels need not be strictly circular either (as with a cylindrical discharge vessel), for example, they may be triangular or rectangular, or simply quadrangular in general. The number of discharge tube members within a lamp 1 may also vary according to size or desired power output of the lamp 1.

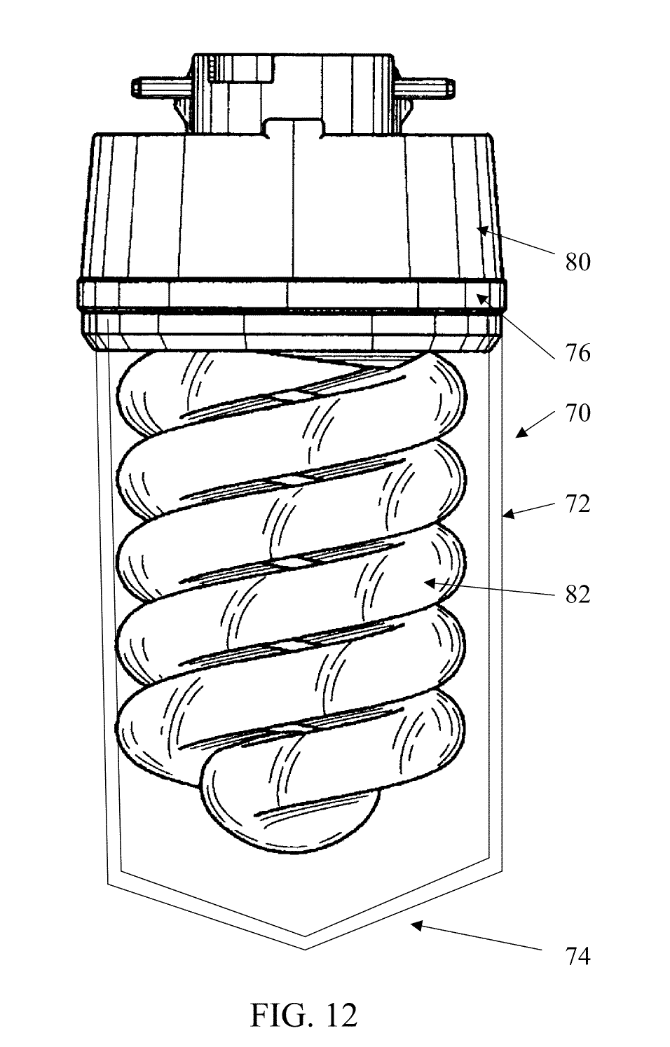

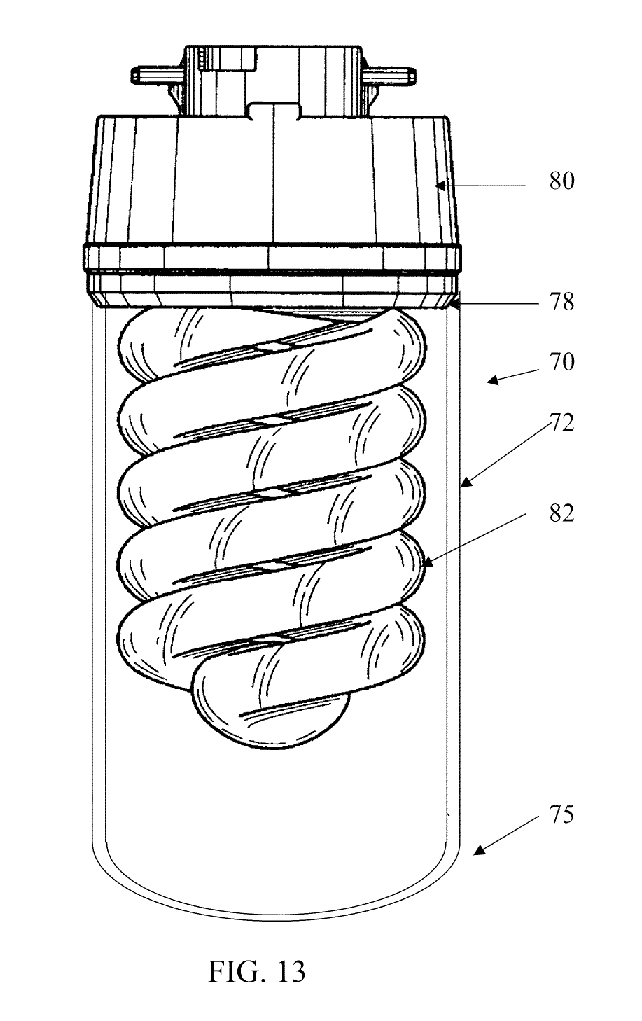

Turning to FIG. 12, a further embodiment of the invention is depicted, which is an outer envelope 70 sealed to the base 80 of a conventional compact fluorescent bulb 82 such as that of U.S. Pat. No. D529,636 S. The outer envelope 70 is shown having a cylindrical portion 72 and a conical portion 74. The conical portion 74 closes a distal end of the cylindrical portion 72. The proximal end of the cylindrical portion 72, i.e., distal from the conical portion 73, is sealed to the lamp base 80 via a sealing structure. The sealing structure is exemplified by a band 76, which is tightened to press an open end of the outer envelope 70 about an outer circumference of the lamp base 80 so as to seal the open end closed. The band 76 may be endless and elastic or be split but closed with a pipe clamp or the like. If the band 76 is elastic, its diameter in its relaxed state should be smaller than a diameter of the lamp base 80 to enable the elastic properties of the band to exert a force against the open end of the outer envelope 70 to seal the same against the lamp base 80. If the band is split, the pipe clamp or the like squeezes together the split so that the band tightly wraps about the outer circumference of the lamp base 80 to seal the same.

Turning to FIG. 13, another embodiment of the invention is depicted, which is an outer envelope 70 sealed to the base 80 of a conventional compact fluorescent bulb 82 such as that of U.S. Pat. No. D529,636 S. The outer envelope 70 is shown having a cylindrical portion 72 and a hemispherical portion 75. The hemispherical portion 75 closes a distal end of the cylindrical portion 72. The proximal end of the cylindrical portion 72, i.e., distal from the hemispherical portion 75, is sealed to the lamp base 80 via a sealing structure. The sealing structure is exemplified by a mechanical structure 78, which is engaged to secure an open end of the outer envelope 70 onto the lamp base 80 so as to seal the open end closed. The mechanical structure 78 may be screw threads on the outer facing side of the open end of the cylindrical portion 72 of the outer envelope that engage complementary screw threads on the inner facing side of the open end of the lamp base 80. Alternatively, the outer envelope may be wider that shown in FIG. 13 and provided with screw threads on the inner facing side of the open end of the cylindrical portion 72 that engage with complementary screw threads provided instead on the outer facing side of the open end of the lamp base 80.

As a further alternative, the mechanical structure 78 of FIG. 13 may be tongue and groove type connections that snap together as the open ends of the cylindrical portion 72 and the lamp base 80 are brought together into engagement with each other. This snapping together creates the seal. Instead of tongue and groove type connections, any other kind of mechanical connections that snap together may be used, such as socket and plug, dovetail and socket, and other kinds of male and female connections. Alternatively, the sealing structure may be an adhesive, such as an epoxy, and used to seal the cylindrical portion 72 to the lamp base 80.

In all the embodiments, the plastic material of the outer envelope should be capable of withstanding the highest rated temperature generated by heat from the compact fluorescent bulbs within so that the integrity of the outer envelope is maintained during normal operation of the bulbs. Some compact fluorescent bulbs are designed to give off heat at lower temperatures than others, that is, they are cooler. Thus, the choice of plastic material for the outer envelope may be rated to withstand a lesser temperature and thereby cost less to manufacture.

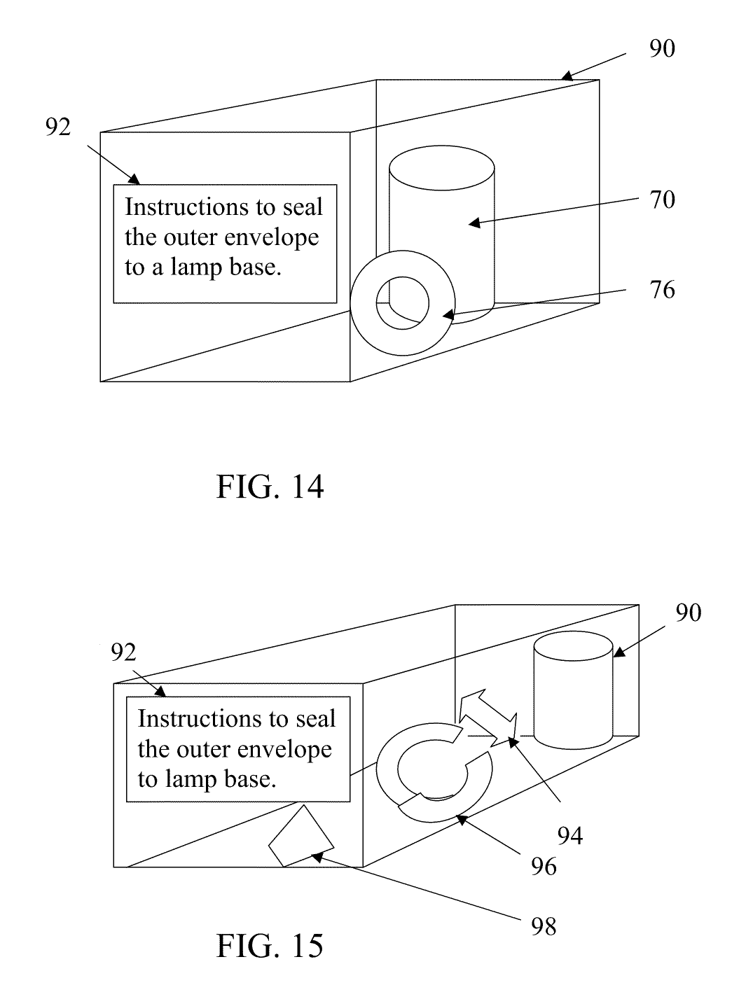

Turning to FIG. 14, a kit is shown that has the outer envelope 70 and the sealing structure (e.g., band 76 of FIG. 12) may be packaged together as a kit in a common package 90 and sold together, but separate from the compact fluorescent lamp. Further, instructions that explain how to use the sealing structure to seal the outer envelope 70 to the lamp base 80 may be printed on the common package 90 itself or on a removable insert 92 (such as a loose card) within the common package. Either way, the print is part of a printed layer. The card may be laminated so that the print of the printed layer doesn't smudge when handled.

Turning to FIG. 15, a further kit is shown that has the outer envelope 70 and the sealing structure (e.g., a clamp 96 that opens or closes in the direction of double arrow 94, a container of adhesive 98) may be packaged together as a kit in a common package 90 and sold together, but separate from the compact fluorescent lamp. Further, instructions that explain how to use the sealing structure to seal the outer envelope 70 to the lamp base 80 may be printed on the common package 90 itself or on a removable insert 92 (such as a loose card) within the common package. Either way, the print is part of a printed layer. The card may be laminated so that the print of the printed layer doesn't smudge when handled.

In all the embodiments, the outer envelope is unbreakable and shatter proof under normal operating conditions because its construction is that of a flexible plastic. Such a construction distinguishes over the use of glass as the material for the outer envelope, because glass is breakable and may shatter when subjected to a highly concentrated force. Thus, a glass outer envelope fails to prevent mercury in the lamp from escaping to the environment if the glass breaks or shatters in the situation in which the glass tube of the compact fluorescent lamp also breaks to release the mercury into the outer envelope.

Further, in all the embodiments, the outer envelope and the sealing structure may be integrated into a unitary construction and need not be separate components. For instance, the open end of the outer envelope may be formed along its periphery as the elastic band 76 or be equipped with an endless sleeve along its periphery that defines a channel into which is housed the elastic band 76.

What is claimed is:

1. A compact fluorescent lamp comprising a glass tube that contains an inert gas and mercury, the glass tube having an inner surface coated with a fluorescent phosphor; a circuit configured to cause electrical current to flow through the inert gas in the glass tube to stimulate atoms of the mercury, which release ultraviolet photons, which in turn stimulate the fluorescent phosphor to emit visible light photons that effect illumination; a lamp base connecting the glass tube to a power supply through a socket to power the circuit; an outer envelope enclosing the glass tube and having an open end; and a sealing structure arranged to close and hermetically seal the open end of the outer envelope, the outer envelope being formed of a flexible plastic material that is non-breakable and shatter proof and resistant to tearing from shards of glass in the event of breakage of the glass tube within the outer envelope and that maintains an integrity of the outer envelope throughout an exposure of the outer envelope to heat given off from the glass tube as a consequence of stimulating the mercury atoms by the electrical current to ultimately stimulate the fluorescent phosphor to emit the visible light photons to effect the illumination.

2. The lamp of claim 1, wherein the sealing structure is a band tightened to press the outer envelope in a vicinity of the open end of the outer envelope against the lamp base in a manner that hermetically seals to prevent an escape of the mercury to the environment from the outer envelope upon release of the mercury from the glass tube due to breakage.

3. The lamp of claim 2, wherein the band is made of an elastic material sized to exert a resilient force to secure the outer envelope to the lamp base.

4. The lamp of claim 2, further comprising a clamp that closes to press the band in a secured manner onto the lamp base.

5. The lamp of claim 1, wherein the sealing structure is an adhesive that hermetically seals to prevent an escape of the mercury to the environment from the outer envelope upon release of the mercury from the glass tube due to breakage.

6. The lamp of claim 1, wherein the sealing structure are screw threads that engage each other, the screw threads being formed in a complementary manner on an outer surface of the lamp base and an inner face of the outer envelope in a vicinity of the open end of the outer envelope.

7. The lamp of claim 1, wherein the sealing structure includes complementary components that snap together upon being brought into engagement with each other to secure the outer envelope in a vicinity of the open end to the lamp base in a hermetically sealed manner to prevent an escape of the mercury to the environment from the outer envelope upon release of the mercury from the glass tube due to breakage.

8. A kit, comprising a package containing an outer envelope and a sealing structure, the outer envelope having an open end and being sized to enclose a glass tube of a compact fluorescent lamp that contains an inert gas and mercury, the sealing structure being configured to hermetically seal the outer envelope to a lamp base in a vicinity of the open end of the outer envelope, the outer envelope being formed of a flexible plastic material that is on-breakable and shatter proof and resistant to tearing from shards of glass in the event of breakage of the glass tube within the outer envelope and that maintains an integrity of the outer envelope throughout an exposure of the outer envelope to heat given off from the glass tube as a consequence of stimulating mercury atoms by the electrical current to ultimately stimulate fluorescent phosphor to emit the visible light photons to effect illumination from within the glass tube.

9. The kit of claim 8, wherein the sealing structure is a band tightened to press the outer envelope in a vicinity of the open end of the outer envelope against the lamp base in a manner that hermetically seals to prevent an escape of the mercury to the environment from the outer envelope upon release of the mercury from the glass tube due to breakage.

10. The kit of claim 9, wherein the band is made of an elastic material sized to exert a resilient force to secure the outer envelope to the lamp base.

11. The kit of claim 9, further comprising a clamp that closes to press the band in a secured manner onto the lamp base.

12. The kit of claim 8, wherein the sealing structure is an adhesive that hermetically seals to prevent an escape of the mercury to the environment from the outer envelope upon release of the mercury from the glass tube due to breakage.

13. The kit of claim 8, wherein the sealing structure are screw threads that engage each other, the screw threads being formed in a complementary manner on an outer surface of the lamp base and an inner face of the outer envelope in a vicinity of the open end of the outer envelope.

14. The kit of claim 8, wherein the sealing structure includes complementary components that snap together upon being brought into engagement with each other to secure the outer envelope in a vicinity of the open end to the lamp base in a hermetically sealed manner to prevent an escape of the mercury to the environment from the outer envelope upon release of the mercury from the glass tube due to breakage.

15. The kit of claim 8, further comprising a printed layer on the package that is configured to instruct how to secure the outer envelope to the lamp base with the sealing structure.

16. The kit of claim 8, further comprising an insert within confines of the package, the insert having a printed layer that is configured to instruct how to secure the outer envelope to the lamp base with the sealing structure
